(19) United States
(12) Patent Application Publication
(10) Pub. No.: US 2011/0303277 A1
(43) Pub. Date: Dec. 15, 2011

(54) TRANSPARENT, WEATHERING-RESISTANT BARRIER FILM, PRODUCTION BY LAMINATION, EXTRUSION LAMINATION OR EXTRUSION COATING

(75) Inventors: Claudius Neumann, Rossdorf (DE); Florian Schwager, Muenster (DE); Ghirmay Seyoum, Egelsbach (DE); Ekkehard Beer, Bad Schwalbach (DE)

(73) Assignee: EVONIK ROEHM GmbH, Darmstadt (DE)

(21) Appl. No.: 13/146,218

(22) PCT Filed: Jan. 21, 2010
(86) PCT No.: PCT/EP10/50667

§ 371 Date: Aug. 30, 2011

(30) Foreign Application Priority Data
Jan. 28, 2009 (DE) 10 2009 000 450.5

(51) Int. Cl. H01L 31/0216; B32B 7/12; B32B 5/00; B32B 37/00; C23C 14/30; B32B 38/00; B32B 37/15; C23C 14/24; C23C 14/34; B32B 27/08; B32B 37/12

(52) U.S. Cl. 136/256; 428/688; 428/522; 428/339; 428/447; 428/335; 156/60; 156/151; 156/244.11; 427/296; 204/192.1; 427/596

(57) ABSTRACT

The invention relates to a barrier film, in which a backing film (4) containing an inorganic barrier (3) (SiOₓ or AlOₓ) is combined with a weather-resistant protective layer (1) using lamination or extrusion coating, an adhesion promoter being used as the adhesive layer (2).

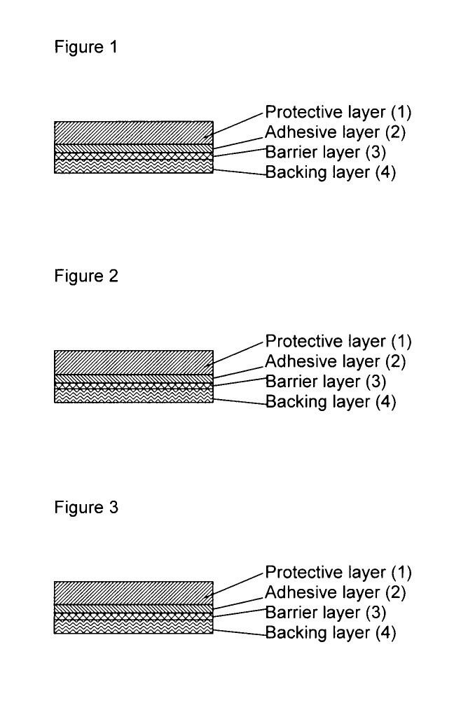

### FIELD OF THE INVENTION

The invention relates to the production of a transparent, weathering-resistant barrier foil by lamination, extrusion lamination (adhesive lamination, melt lamination or hotmelt lamination), or extrusion coating. To this end, a thin, inorganically coated, transparent foil (e.g. PET) is laminated with a weathering-resistant, transparent foil (e.g. PMMA or PMMA-polyolefin coextrudate). The inorganic oxide layer acts as a high, transparent barrier with respect to water vapor and oxygen, while the PMMA layer provides the weathering resistance.

### PRIOR ART

Weathering-resistant, transparent, and impact-resistant foils based on polymethacrylate are marketed by the applicant as PLEXIGLAS®. The patent DE 38 42 796 A1 describes the production of a clear, impact-resistant molding composition based on acrylate, moldings and foils produced therefrom, and also a process for producing the molding composition. Said foils have the advantage that when exposed to heat and moisture they do not discolor and/or become brittle. They moreover avoid what is known as stress whitening when exposed to impact or flexural stress. Said foils are transparent and remain transparent even when exposed to heat and moisture, and when subjected to weathering, and when subjected to impact or flexural stress.

The processing of the molding composition to give the abovementioned transparent, impact-resistant foils ideally takes place by extrusion of the melt through a flat-film die and polishing on a set of rolls. Foils of this type feature longlasting clarity, resistance to heat and low temperatures, weathering resistance, little tendency to yellow and embrittle, and little stress whitening when subjected to buckling or creasing, and they are therefore suitable by way of example as windows in tarpaulins, soft tops, or sails. The thickness of foils of this type is below 1 mm, for example from 0.02 to 0.5 mm. An important application sector is the formation of thin surface layers, for example a thickness from 0.02 to 0.5 mm, on rigid, dimensionally stable bases, such as sheet metal, paperboard, particle board, plastics sheet, and the like. There are various processes available for producing these types of coverings. By way of example, the foil can be extruded to give a molding composition, and polished, and laminated onto the substrate. The extrusion coating technique can be used to apply an extrudate to the surface of the substrate, and a roll can be used to polish the extrudate. If the substrate itself makes use of a thermoplastic, it is possible to coextrude the two compositions and thus form a surface layer from the clear molding composition of the invention.

However, PMMA foils do not provide satisfactory barrier properties with respect to water vapor and oxygen, whereas this is necessary for medical applications, applications in the packaging industry, and especially in outdoor electrical applications.

Transparent, inorganic layers are applied to polymer foils to improve barrier properties. Silicon oxide layers and aluminum oxide layers have been particularly widely used. This inorganic oxide layer (SiOₓ or AlOₓ) is applied by the vacuum coating process (chemically, JP-A-10025357, JP-A-07074378; or a thermal or electron-beam vaporization process, or sputtering, EP 1 018 166 B1, JP 2000-307136 A, WO 2005-029601 A2). EP 1018166 B1 says that the UV absorption of the SiOₓ layer can be influenced by way of the silicon to oxygen ratio in the SiOₓ layer. This is important, in order that layers located thereunder are protected from UV radiation. However, the disadvantage is that when the silicon to oxygen ratio is altered the barrier property also changes. It is not therefore possible to achieve variation of transparency and barrier independently of one another.

The inorganic oxide layer is mainly applied on polyesters and polyolefins, since these materials withstand the thermal stress of the vaporization process. The inorganic oxide layer moreover has good adhesion on polyesters and polyolefins, where the latter are subjected to corona treatment prior to the coating process. However, since these materials are not weathering-resistant, they are frequently laminated with halogenated foils, as described by way of example in WO 94/29106, but halogenated foils are not environmentally friendly.

As is known from U. Moosheimer, Galvanotechnik 90 No. 9, 1999, pp. 2526-2531, the coating of PMMA with an inorganic oxide layer does not improve the barrier with respect to water vapor and oxygen, since PMMA is amorphous. However, unlike polyesters and polyolefins, PMMA is weathering-resistant.

The applicant uses coatings called “antigraffiti coating”, which have excellent adhesion on PMMA (DE 102007007999 A1). A fluorinated methacrylate provides the antigraffiti effect. Said coatings can provide excellent adhesion to SiOₓ layers if the fluorinated component is replaced by a siloxane-containing component. The advantage of these coatings is that they have excellent long-term resistance to natural weathering.

### OBJECT

The invention is based on the object of providing a barrier foil which is weathering-resistant and highly transparent (>80% in the wavelength region >300 nm), while providing a high level of barrier properties with respect to water vapor and oxygen. The weathering-resistance property is provided by PMMA, and the barrier properties are provided by the inorganic oxide layer. A first object of the present invention is to combine PMMA as backing layer with an inorganic oxide layer. A second intention is that the function of protection from UV radiation be assumed by the PMMA layer rather than, as heretofore, by the inorganic oxide layer, in order that the latter can be optimized exclusively on the basis of optical criteria. A third intention is that this combination of materials achieve a partial discharge voltage greater than 1000 V.

### ACHIEVEMENT OF OBJECT

The object is achieved through a barrier foil which is weathering-resistant. The properties are achieved through a multilayer foil where the individual layers are combined with one another by vacuum deposition, lamination, extrusion lamination (adhesive lamination, melt lamination, or hotmelt lamination), or extrusion coating. Conventional processes as described by way of example in S. E. M. Selke, J. D. Cutter, R. J. Hernandez, “Plastics Packaging”, 2nd edition, Hanser-Verlag, ISBN 1-56990-372-7 on pp. 226 and 227, can be used for this purpose.

Since the direct inorganic coating of PMMA is not possible according to the prior art, the inorganic layer is vapor-deposited onto a polyester foil or polyolefin foil, and PMMA is laminated or extrusion-laminated with said layer. The PMMA layer protects the polyester foil or polyolefin foil from the effects of weathering. The adhesion between the inorganic layer and the PMMA layer is provided by an acrylate-based adhesion promoter which is UV-curable, and which comprises siloxane groups. It is also possible to use a hotmelt adhesive.

The PMMA layer moreover comprises a UV absorber, which protects the polyester foil or polyolefin foil from UV radiation. However, it is also possible that the UV absorber is present in the polyolefin layer. Instead of the PMMA layer, it is also possible to use a coextrudate made of PMMA and polyolefin, with cost advantages, since polyolefins are less expensive than PMMA.

### Advantages of the Invention

The barrier foil of the invention is weathering-resistant.
The barrier foil of the invention is halogen-free.
The barrier foil of the invention comprises a high barrier with respect to water vapor and oxygen (21 0.1 g/(m² d)).
The barrier foil of the invention protects layers located thereunder from UV radiation independently of the constitution of the SiOₓ layer.
The barrier foil of the invention can be produced at low cost, since a thin foil can be used for the batch inorganic vacuum deposition process.

The Protective Layer

The protective layer used comprises foils made preferably of polymethyl methacrylate (PMMA) or of impact-resistant PMMA (irPMMA). It is also possible to use coextrudates made of polymethacrylates and of polyolefins or of polyesters. Preference is given to coextrudates made of polypropylene and PMMA. Another possibility is a fluorinated, halogenated layer, e.g. a coextrudate made of PVDF with PMMA, or a blend made of PVDF and PMMA, although the advantage of freedom from halogen would be lost here. The thickness of the protective layer is from 20 μm to 500 μm, preferably from 50 μm to 400 μm, and very particularly preferably from 200 μm to 300 μm.

Light stabilizers can be added to the backing layer in the invention. Light stabilizers are UV absorbers, UV stabilizers, and free-radical scavengers.

Examples of UV stabilizers optionally present are derivatives of benzophenone, the substituents of which, e.g. hydroxy and/or alkoxy groups, are mostly located in 2- and/or 4-position. Among these compounds are 2-hydroxy-4-n-octoxybenzophenone, 2,4-di-hydroxybenzophenone, 2,2′-dihydroxy-4-methoxybenzophenone, 2,2′,4,4′-tetra-hydroxybenzophenone, 2,2′-dihydroxy-4,4′-dimethoxybenzophenone, 2-hydroxy-4-methoxybenzophenone. Substituted benzotriazoles are also very suitable as UV-protection additive, and among these especially 2-(2-hydroxy-5-methylphenyl)-benzotriazole, 2-[2-hydroxy-3,5-di(alpha,alpha-dimethyl-benzyl)phenyl]benzotriazole, 2-(2-hydroxy-3,5-di-tert-butylphenyl)benzotriazole, 2-(2-hydroxy-3,5-dibutyl-5-methyl-phenyl)-5-chlorobenzotriazole, 2-(2-hydroxy-3,5-di-tert-butylphenyl)-5-chlorobenzo-triazole, 2-(2-hydroxy-3,5-di-tert-amylphenyl)benzotriazole, 2-(2-hydroxy-5-tert-butylphenyl)benzotriazole, 2-(2-hydroxy-3-sec-butyl-5-tert-butylphenyl)benzotriazole and 2-(2-hydroxy-5-tert-octylphenyl)benzotriazole, phenol, 2,2′-methylenebis[6-(2H-benzotriazol-2-yl)-4-(1,1,3,3-tetramethylbutyl)].

Another UV absorber that can be used, alongside the benzotriazoles, is one from the class of the 2-(2′-hydroxyphenyl)-1,3,5-triazines, for example phenol-2-(4,6-diphenyl-1,2,5-triazine-2-xy)-5-(hexyloxy).

Other UV stabilizers that can be used are ethyl 2-cyano-3,3-diphenylacrylate, oxalic bis(2-ethoxy-2′-ethylanilide), oxalic bis(2-ethoxy-5-tert-butyl-2′-ethylanilide), and substituted phenyl benozates.

The light stabilizers or UV stabilizers can be present in the form of low-molecular-weight compounds, as stated above, in the polymethacrylate compositions to be stabilized. However, it is also possible that there are UV-absorbent groups covalently bonded within the matrix polymer molecules, after copolymerization with polymerizable UV-absorption compounds, e.g. acrylic, methacrylic, or allyl derivatives of benzophenone derivatives or benzotriazole derivatives.

The proportion of UV stabilizers, where these can also be mixtures of chemically different UV stabilizers, is generally from 0.01 to 10% by weight, especially from 0.01 to 5% by weight, in particular from 0.02 to 2% by weight, based on the (meth)acrylate copolymer.

Examples that may be mentioned here of free-radical scavengers/UV stabilizers are sterically hindered amines, where these are known as HALS (hindered amine light stabilizer). They can be used for inhibiting aging processes in coatings and plastics, especially in polyolefin plastics (Kunststoffe, 74 (1984) 10, pp. 620 to 623; Farbe+Lack, volume 96, 9/1990, pp. 689 to 693). The tetramethylpiperidine group present in the HALS compounds is responsible for the stabilizing effect. The piperidine nitrogen in this class of compound can have either no substitution or else substitution by alkyl or acyl groups. The sterically hindered amines do not absorb in the UV region. They scavenge radicals that have been formed, whereas the UV absorbers cannot do this. Examples of HALS compounds that have stabilizing effect, where these can also be used in the form of mixtures, are:

bis(2,2,6,6-tetramethyl-4-piperidyl) sebacate, 8-acetyl-3-dodecyl-7,7,9,9-tetramethyl-1,3,8-triazaspiro(4,5)decane-2,5-dione, bis(2,2,6,6-tetramethyl-4-piperidyl) succinate, poly(N-β-hydroxyethyl-2,2,6,6-tetramethyl-4-hydroxypiperidine succinate), or bis(N-methyl-2,2,6,6-tetramethyl-4-piperidyl) sebacate.

Examples of particularly preferred UV absorbers are Tinuvin® 234, Tinuvin® 360, Chimasorb® 119 or Irganox® 1076.

The amounts used of the free-radical scavengers/UV stabilizers in the polymer mixtures of the invention are from 0.01 to 15% by weight, especially from 0.02 to 10% by weight, in particular from 0.02 to 5% by weight, based on the (meth)acrylate copolymer.

The UV absorber is preferably in the PMMA layer, but can also be present in the polyolefin layer or polyester layer.

The protective layer moreover has sufficient layer thickness to provide the partial discharge voltage of 1000 V. This depends on the thickness and by way of example in the case of PMMA is 250 μm or greater. The partial discharge voltage is the voltage required for an electrical discharge which partially bridges insulation (see DIN EN 60664-1).

The Backing Layer

The backing layer used comprises foils made preferably of polyolefins (PE, PP) or of polyesters (PET, PEN). It is also possible to use foils made of other polymers (for example polyamides or polylactic acid). The thickness of the backing layer is from 1 μm to 100 μm, preferably from 5 μm to 50 μm, and very particularly preferably from 10 μm to 30 μm.

The transparency of the backing layer is more than 80%, preferably more than 85%, particularly preferably more than 90%, in the wavelength region >300 nm, preferably from 350 to 2000 nm, particularly preferably from 380 to 800 nm.

The Barrier Layer

The barrier layer has been applied to the backing layer and is preferably composed of inorganic oxides, such as SiOₓ or AlOₓ. However, it is also possible to use other inorganic materials (such as SiN, SiNₓO_{y}, ZrO, TiO₂, ZnO, FeₓO_{y}, or transparent organometallic compounds). See the inventive examples for the precise layer structure. SiOₓ layers preferably used are layers where the ratio of silicon and oxygen is from 1:1 to 1:2, particularly preferably from 1:1.3 to 1:1.7. The layer thickness is from 5 to 300 nm, preferably from 10 to 100 nm, particularly preferably from 20 to 80 nm. The AlOₓ layers used are preferably layers where the ratio of aluminum and oxygen is 2:3. The layer thickness is from 5 to 300 nm, preferably from 10 to 100 nm, particularly preferably from 20 to 80 nm.

The inorganic oxides can be applied by means of physical vacuum deposition (electron-beam process or thermal process), magnetron sputtering, or chemical vacuum deposition. Other possibilities are flame treatment, plasma treatment, or corona treatment.

The Adhesive Layer

The location of the adhesive layer is between protective layer and barrier layer. It permits adhesion between the two layers. The thickness of the adhesive layer is from 1 to 100 μm, preferably from 2 to 50 μm, particularly preferably from 2 to 20 μm. The adhesive layer can be formed from a coating formulation which is subsequently hardened. This is preferably achieved through UV radiation, but can also be achieved thermally. The adhesive layer comprises from 1 to 80% by weight of polyfunctional methacrylates or acrylates, or a mixture thereof, as main component. It is preferable to use polyfunctional acrylates, e.g. hexanediol dimethycrylate. Monofunctional acrylates or methacrylates can be added to increase flexibility, an example being hydroxyethyl methacrylate or lauryl methacrylate. The adhesive layer also optionally comprises a component which improves adhesion to SiOₓ, examples being methacrylates or acrylates comprising siloxane groups, e.g. methacryloxypropyltrimethoxysilane. The amount present of the methacrylates or acrylates comprising silanoxane groups in the adhesive layer can be from 0 to 48% by weight. The adhesive layer comprises from 0.1 to 10% by weight, preferably from 0.5 to 5% by weight, particularly preferably from 1 to 3%, of an initiator, e.g. Irgacure® 184 or Irgacure® 651. The adhesive layer can also comprise, as chain-transfer agent, from 0 to 10% by weight, preferably from 0.1 to 10% by weight, particularly preferably from 0.5 to 5%, of sulfur compounds. In one variant, a portion of the main component is replaced by from 0 to 30% by weight of prepolymer. The adhesive component optionally comprises from 0 to 40% by weight of the additives conventional in adhesives. However, the adhesive layer can also be formed from a hotmelt adhesive. This can be composed of polyamides, of polyolefins, of thermoplastic elastomers (polyester elastomers, polyurethane elastomers, or copolyamide elastomers), or of copolymers. Preference is given to ethylene-vinyl acetate copolymers or ethylene-acrylate copolymers, or ethylene-methacrylate copolymers. The adhesive layer can be applied by means of roll-application processes in the lamination process, or by means of a die in the extrusion lamination process or in the extrusion coating process.

Use

This barrier foil can be used in the packaging industry, in display technology, in organic photovoltaic systems, in thin-layer photovoltaic systems, in crystalline silicon modules, and also for organic LEDs.

Inventive Examples

1. Protective layer—barrier layer—backing layer, lamination

A backing layer (4) (e.g. PET) is coated with a barrier layer (3) (e.g. SiOₓ). The protective layer (1) (e.g. PMMA) is applied thereto by lamination. By way of example, an acrylate- or methacrylate-based adhesion promoter can be used as adhesive layer (2) for the lamination process. This adhesion promoter can be applied by roll-application processes (roll coating or kiss coating). A feature of the protective layer (1) is that it comprises a UV absorber.

Process:
1. Vacuum coating (PVD, CVD) of the backing layer (4)
2. Application of the protective layer (1) to the barrier layer (3) by means of lamination (roll-application process) using an adhesion promoter, which represents the adhesive layer (2)
3. Hardening of the adhesive layer (2) by UV radiation

2. Protective layer—barrier layer—backing layer, extrusion coating

A backing layer (4) (e.g. PET) is coated with a barrier layer (3) (e.g. SiOₓ). Extrusion coating is then used to apply the protective layer (1) in the molten state (e.g. PMMA-PP coextrudate). The adhesion of the protective layer on the barrier layer can optionally be improved through an adhesive layer (2), e.g. acrylate- or methacrylate-based adhesion promoter, or hotmelt adhesive, e.g. based on ethylene-acrylate copolymer.

A feature of the protective layer (1) is that it comprises a UV absorber and that it is composed of two or three layers (PMMA and PP or PMMA, adhesion promoter or hotmelt adhesive, and PP).

Process:
1. Vacuum coating (PVD, CVD) of the backing layer (4)
2. Application of the protective layer (1) to the barrier layer (3) by means of multilayer extrusion coating, possibly with use of a hotmelt adhesive, which represents the adhesive layer (2)

3. Protective layer—barrier layer—backing layer, extrusion lamination

A backing layer (4) (e.g. PET) is coated with a barrier layer (3) (e.g. SiOₓ). Extrusion lamination is then used to apply the protective layer (1) (e.g. PMMA or coextrudates made of PMMA and of polyolefins). The adhesive layer (2) used for the lamination process can by way of example comprise a hotmelt adhesive, e.g. based on ethylene-acrylate copolymer. This hotmelt adhesive is extruded by means of a die in the molten state between the protective layer (1) and the backing layer (4) comprising the barrier layer (3). A feature of the protective layer (1) is that it comprises a UV absorber.

Process:
1. Vacuum coating (PVD, CVD) of the backing layer (4)
2. Extrusion lamination of the adhesive layer (2) in the molten state between the protective layer (1) and the backing layer (4) comprising the barrier layer (3)

Measurement of the Barrier Provided by the Foil of the Invention

The water-vapor transmission of the foil system is measured to ASTM F1249 at 23° C./85% rel. humidity.

The partial discharge voltage is measured to DIN 61730-1 and IEC 60664-1 or DIN EN 60664-1.

### EXAMPLES

### Comparative Example

A foil of the prior art (EP 1 018 166 B1), e.g. SiOₓ-coated ETFE with layer thickness 50 μm, has a water vapor transmission of 0.7 g/(m² d).

A foil of the invention with layer thickness 50 μm for the backing layer has a water vapor permeation rate from 0.01 to 0.1 g/(m² d) (see inventive example 1).

1. Protective layer: PMMA, layer thickness 50 μm, comprises 1% of Tinuvin® 234 UV absorber.

Adhesive layer: 62% of Laromer UA 9048 V, 31% of hexanediol dimethacrylate, 2% of hydroxyethyl methacrylate, 3% of Irgacure 651, 2% of 3-methacryloxypropyltrimethoxy-silane

Barrier layer: SiO_{1.5} applied by means of an electron-beam vacuum vaporization process, layer thickness: 40 nm.

Backing layer: Mitsubishi Hostaphan RN12 PET, layer thickness: 12 μm.

2. Protective layer: impact-resistant PMMA, layer thickness: 250 μm, comprises 2% of Cesa Light® GXUVA006 UV absorber.

Adhesive layer: 62% of Laromer UA 9048 V, 31% of hexanediol diacrylate, 2% of hydroxyethyl methacrylate, 3% of Irgacure 184, 2% of butyl acrylate

Barrier layer: Al₂O₃, layer thickness 40 nm, applied by means of magnetron sputtering.

Backing layer: PEN, layer thickness: 20 μm.

3. Protective layer: coextrudate made of PMMA and of impact-resistant PMMA, layer thickness 150 μm, comprises 1.5% of Tinuvin® 360 UV absorber.

Adhesive layer: 62% of Ebecryl 244, 31% of hexanediol diacrylate, 2% of hydroxyethyl methacrylate, 3% of Irgacure 651, 2% of glymo

Barrier layer: SiO_{1.7}, layer thickness 80 nm, applied by means of magnetron sputtering.

Backing layer: PET, layer thickness 23 μm.

4. Protective layer: coextrudate made of impact-resistant PMMA (e.g. Plex 8943F), layer thickness 40 μm, comprises 1.5% of Tinuvin® 360 UV absorber, and polyethylene (e.g. Dowlex SC 2108 G), layer thickness 200 μm; adhesion promoter: Bynel 22 E 780 (ethylene-acrylate copolymer) from DuPont.

Adhesive layer: Bynel 22 E 780 from DuPont

Barrier layer: SiO_{1.7}, layer thickness 80 nm, applied by means of an electron-beam vacuum vaporization process.

Backing layer: Mitsubishi Hostaphan RN75 PET, layer thickness 75 μm.

5. Protective layer: coextrudate made of impact-resistant PMMA and PP, total layer thickness 280 μm, comprises 1.5% of Tinuvin® 360 UV absorber; adhesion promoter between PMMA and PP: Bynel; layer thicknesses PMMA-Bynel-PP: 210-30-30 μm

### KEY

1 Protective layer

2 Adhesive layer

3 Barrier layer

4 Backing layer

1. A barrier foil, comprising:
a weathering-resistant protective layer; and
a backing layer comprising a barrier layer,
wherein the protective layer is weathering-resistant, and
wherein the barrier layer, comprising at least one inorganic oxide, improves a barrier effect with respect to water vapor and oxygen.

2. The foil of claim 1, which is halogen-free.

3. The foil of claim 1, having a partial discharge voltage of at least 1000 V.

4. The foil of claim 1, having a transparency of more than 80% in a region >300 nm.

5. The foil of claim 1, further comprising, between the inorganic barrier layer and the protective layer;
an adhesive layer which comprises an adhesion promoter comprising:
a) from 1 to 80% by weight of at least one selected from the group consisting of a mono- or polyfunctional acrylate, a monofunctional methacrylate, and a polyfunctional methacrylate;
b) from 0 to 30% by weight of a prepolymer;
c) from 0 to 48% by weight of a methacrylate or acrylate comprising siloxane groups;
d) from 0.1 to 10% by weight of at least one initiator;
e) from 0 to 10% by weight of at least one chain-transfer agent; and
f) from 0 to 40% by weight of at least one conventional additive.

6. The foil of claim 1, further comprising, between the inorganic barrier layer and the protective layer;
an adhesive layer comprising a hotmelt adhesive.

7. A process for producing the foil of claim 1, comprising
a) inorganically coating a backing foil comprising at least one selected from the group consisting of a polyolefin, and a polyester by a vacuum vaporization process or sputtering, combining foil by lamination with a weathering-resistant plastics foil PMMA, a coextrudate comprising PMMA, and a polyolefin, or
b) inorganically coating a backing foil comprising at least one selected from the group consisting of a polyolefin, and a polyester by a vacuum vaporization process or sputtering, combining foil by extrusion lamination with a weathering-resistant plastics foil PMMA, a coextrudate comprising PMMA, and a polyolefin, or
c) inorganically coating a backing foil comprising at least one selected from the group consisting of a polyolefin, and a polyester by a vacuum vaporization process or sputtering, combining foil by extrusion coating with a weathering-resistant plastics foil PMMA, a coextrudate comprising PMMA, and a polyolefin, and
d) in physical vacuum vaporization, b), or a) to c), vaporizing SiO with an electron beam, or
e) in physical vacuum vaporization, b), or a) to c), thermally vaporizing SiO.

8. Packaging, a display, or an organic LED, comprising the film of claim 1.

9. An organic photovoltaic system, a thin-layer photovoltaic system, or a crystalline silicon module, comprising the film of claim 1.

10. The foil of claim 1, wherein the protective layer has a thickness of from 20 μm to 500 μm.

11. The foil of claim 1, wherein the protective layer has a thickness of from 50 μm to 400 μm.

12. The foil of claim 1, wherein the protective layer has a thickness of from 200 μm to 300 μm.

13. The foil of claim 1, having a transparency of more than 85% in a region >300 nm.

14. The foil of claim 1, having a transparency of more than 90% in a region >300 nm.

15. The foil of claim 1, having a transparency of more than 80% in a wavelength region from 350 to 2000 nm.

16. The foil of claim 1, having a transparency of more than 80% in a wavelength region from 380 to 800 nm.

17. The foil of claim 1, having a transparency of more than 85% in a wavelength region from 350 to 2000 nm.

18. The foil of claim 1, wherein a thickness of the backing layer is from 1 μm to 100 μm.

19. The foil of claim 1, wherein a thickness of the backing layer is from 5 μm to 50 μm.

20. The foil of claim 1, wherein a thickness of the backing layer is from from 10 μm to 30 μm.
